(19) United States
(12) Patent Application Publication
(10) Pub. No.: US 2010/0290331 A1
(43) Pub. Date: Nov. 18, 2010

(54) WIRING STRUCTURE AND OPTICAL DISK APPARATUS

(76) Inventors: Yasuhiro KAIZAKI, Osaka (JP); Tetsuro Sawai, Osaka (JP); Sumitoshi Kawasaki, Osaka (JP)

Correspondence Address: MCDERMOTT WILL & EMERY LLP, 600 13TH STREET, N.W., WASHINGTON, DC, 20005-3096, US

(21) Appl. No.: 12/727,928

(22) Filed: Mar. 19, 2010

(30) Foreign Application Priority Data
May 15, 2009 (JP) 2009-119225
Mar. 8, 2010 (JP) 2010-050603

(51) Int. Cl. G11B 7/00; H05K 1/00

(52) U.S. Cl. 369/100; 174/250; G9B/7

(57) ABSTRACT

A signal current wiring line is configured to carry a signal current from a first circuit block to a second circuit block. A return current wiring line is configured to carry a return current from the second circuit block to the first circuit block. The signal current wiring line and the return current wiring line are stacked with an offset in the width direction so as to form a region between the surface of the casing on the second wiring line side and the signal current wiring line where the signal current wiring line faces the surface of the casing on the second wiring line side without the return current wiring line intervening between them.

### BACKGROUND OF THE INVENTION

This application is based upon and claims the benefit of priority from the prior Japanese Patent Application No. 2009-119225, filed May 15, 2009 and Japanese Patent Application No. 2010-50603, filed on Mar. 8, 2010, the entire contents of which are incorporated herein by reference.

1. Field of the Invention

The present invention relates to a wiring structure which functions as a connection between circuit blocks, and an optical disk apparatus employing the wiring structure.

2. Description of the Related Art

In general, a wiring line through which a return current is to be carried (which will be referred to as a “return current wiring line” hereafter) is provided between circuit blocks between which signals are to be transmitted, in addition to a wiring line through which a signal current is to be carried (which will be referred to as a “signal current wiring line” hereafter). The return current wiring line is provided in the vicinity of the signal current wiring line for the purpose of reducing the area of a region where current loops occur, thereby suppressing electromagnetic wave radiation.

As progress is made in improving the performance and reducing the size of electronic products, the space which can be used to separate wiring lines between circuit blocks also becomes smaller. Accordingly, a method is employed in which the signal current wiring line and the return current wiring line are mounted in a stacked manner.

A casing having a reduced thickness involves a reduction in the distance between the signal current wiring lines and the top face and the bottom face of the casing. This reduced distance leads to increased parasitic capacitance that occurs between each signal current wiring line and the top face and the bottom face of the casing. In particular, an application in which the signal current wiring line is required to be wide leads to an even greater increase in the parasitic capacitance. This is because the capacitance is inversely proportional to the distance between electrodes, and is proportional to the areas of the electrodes. The increased parasitic capacitance leads to increased signal loss in the signal current wiring line.

### SUMMARY OF THE INVENTION

The present invention has been made in view of such a situation. Accordingly, it is a general purpose of the present invention to provide a technique for reducing signal loss that occurs in a signal current wiring line included in a wiring structure in which the signal current wiring line and a return current wiring line are arranged in a stacked manner in a casing.

In order to solve the aforementioned problem, a wiring structure according to an embodiment of the present invention comprises: a first wiring line configured to carry a signal current from a first circuit block to a second circuit block; and a second wiring line provided as a separate layer from that of the first wiring line, and configured to carry a return current from the second circuit block to the first circuit block. The first wiring line and the second wiring line are arranged in a casing, with a predetermined distance between them. With such an arrangement, a region is formed between a surface of the casing on the second wiring line side and the first wiring line where the first wiring line faces the surface of the casing on the second wiring line side without the second wiring line intervening between them.

Another embodiment of the present invention relates to an optical disk apparatus. The optical disk apparatus comprises: a light-emission unit configured to emit laser light toward an optical disk; a driving unit configured to drive the light-emission unit; a first wiring line configured to carry a driving signal current from the driving unit to the light-emission unit; a second wiring line provided as a separate layer from that of the first wiring line, and configured to carry a return current from the light-emission unit to the driving unit. The first wiring line and the second wiring line are arranged in a casing, with a predetermined distance between them. With such an arrangement, a region is formed between a surface of the casing on the second wiring line side and the first wiring line where the first wiring line faces the surface of the casing on the second wiring line side without the second wiring line intervening between them.

It should be noted that any combination of the aforementioned components may be made, and any manifestation thereof may be mutually substituted between a method, apparatus, system, and so forth, which are effective as an embodiment of the present invention.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1A and FIG. 1B are diagrams which show, for the sake of comparison with an embodiment, a casing which stores a first circuit block and a second circuit block;

FIG. 2A and FIG. 2B are diagrams which show a casing which stores a first circuit block and a second circuit block according to an embodiment;

FIG. 3A and FIG. 3B are schematic diagrams for describing parasitic capacitances that occurs in the wiring structures shown in FIG. 1A, FIG. 1B, FIG. 2A and FIG. 2B;

FIG. 4 is a diagram which shows the setting condition used to simulate the relation between an offset and signal loss in the wiring structure according to the embodiment;

FIG. 5 is a graph which shows the simulation result of the relation between the offset and the signal loss in the wiring structure according to the embodiment;

FIG. 6 is a schematic diagram for describing the distance relation between a first face, a signal current wiring line, a return current wiring line, and a second face of the casing;

FIG. 7 is a block diagram which shows a configuration of an optical disk apparatus according to an application;

FIG. 8 is a schematic diagram for describing parasitic capacitance that occurs in the wiring structure according to a modification 1;

FIG. 9 is a schematic diagram for describing parasitic capacitance that occurs in the wiring structure according to a modification 2;

FIG. 10 is a schematic diagram for describing parasitic capacitance that occurs in the wiring structure according to a modification 3; and

FIG. 11 is a schematic diagram for describing parasitic capacitance that occurs in the wiring structure according to a modification 4.

### DETAILED DESCRIPTION OF THE INVENTION

The invention will now be described by reference to the preferred embodiments. This does not intend to limit the scope of the present invention, but to exemplify the invention.

Description will be made below regarding embodiments according to the present invention with reference to the drawings. The same or similar components are denoted by the same reference numerals in the drawings, and redundant description thereof will be omitted as appropriate.

### COMPARISON EXAMPLE

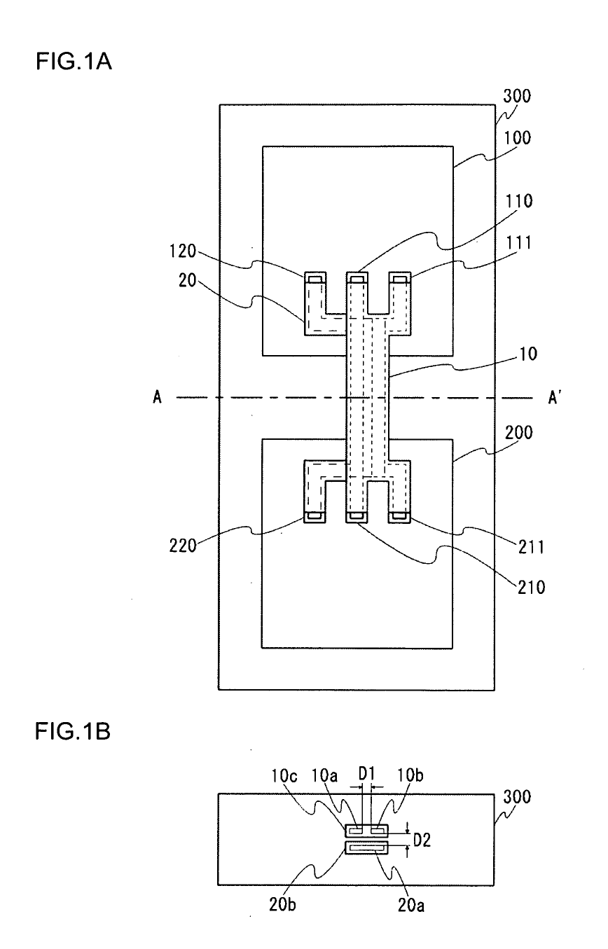

FIG. 1A and FIG. 1B are diagrams which show, for the sake of comparison with the embodiment, a casing 300 which stores a first circuit block 100 and a second circuit block 200. Here, the first circuit block 100 may be a driving circuit. Also, the second circuit block 200 may be a load circuit driven by the driving circuit. Description will be made below regarding an arrangement in which the first circuit block 100 is a laser diode driver, and the second circuit block 200 is a laser diode. It should be noted that description will be made in the present specification under the assumption that the casing 300 is formed of a material which functions as an electrical conductor such as metal or the like.

FIG. 1A is a diagram which shows the interior of the casing 300 viewed from the top. A signal current wiring board 10 and a return current wiring board 20 are provided between the first circuit block 100 and the second circuit block 200. A flexible printed board may be employed as the signal current wiring board 10 and the return current wiring board 20.

The signal current wiring board 10 is a wiring board which electrically connects a first connector 110 of the first circuit block 100 to a first connector 210 of the second circuit block 200, and electrically connects a second connector 111 of the first circuit block 100 to a second connector 211 of the second circuit block 200. The return current wiring board 20 is a wiring board which electrically connects a third connector 120 of the first circuit block 100 to a third connector 220 of the second circuit block 200. The signal current wiring board 10 and the return current wiring board 20 are arranged in a stacked manner with a predetermined space opened between them, midway between the first circuit block 100 and the second circuit block 200.

FIG. 1B is a cross-sectional view of the casing 300 taken along the line A-A′ shown in FIG. 1A. The signal current wiring board 10 includes a first signal current wiring line 10a and a second signal current wiring line 10b. The first signal current wiring line 10a and the second signal current wiring line 10b are arranged within the signal current wiring board 10 such that there is a predetermined distance D1 opened between them in the width direction (the horizontal direction in the Figure). The first signal current wiring line 10a and the second signal current wiring line 10b are each coated with an insulating material (dielectric material) 10c such as a polyimide film or the like, thereby providing electrical insulation between the first signal current wiring line 10a and the second signal current wiring line 10b.

The first signal current wiring line 10a and the second signal current wiring line 10b are each wiring lines via which a signal current is to be carried from the first circuit block 100 to the second circuit block 200. In a case in which the aforementioned laser diode is a type which is capable of emitting two kinds of laser light of two wavelengths respectively used for CDs and DVDs, the first signal current wiring line 10a and the second signal current wiring line 10b transmit the following signals. That is to say, the first signal current wiring line 10a is used to transmit a signal from the laser diode driver to the laser diode, which is used to instruct the laser diode to emit CD reading laser light or CD writing laser light to the surface of a CD (which will be referred to as the “CD signal” hereafter). The second signal current wiring line 10b is used to transmit a signal from the laser diode driver to the laser diode, which is used to instruct the laser diode to emit DVD reading laser light or DVD writing laser light to the surface of a DVD (which will be referred to as the “DVD signal” hereafter).

It should be noted that, in a case in which the aforementioned laser diode is a type which is capable of emitting three kinds of laser light of three wavelengths respectively used for CDs, DVDs, and BDs, the signal current wiring board 10 may include a third signal current wiring line via which a signal is transmitted which is used to instruct the laser diode to emit BD reading laser light or BD writing laser light to the surface of a BD, in addition to the first and second signal current wiring lines.

The return current wiring board 20 includes a return current wiring line 20a. The return current wiring line 20a is coated with and protected by an insulating material 20b such as a polyimide film or the like. The return current wiring line 20a is a wiring wiring line used to carry the return current from the second circuit block 200 to the first circuit block 100.

The wiring line width of the return current wiring line 20a must be designed to be a wiring line width that corresponds to the maximum current that flows through the first signal current wiring line 10a and the second signal current wiring line 10b. With an application in which current does not flow through the first signal current wiring line 10a and the second signal current wiring line 10b at the same time, the wiring line width of the return current wiring line 20a must be designed to be a wiring line width that corresponds to the greater of the maximum current that flows through the first signal current wiring line 10a and the maximum current that flows through the second signal current wiring line 10b. Here, as with a microstrip line, the return current wiring board 20 is designed to function as a ground line for the signal current wiring board 10.

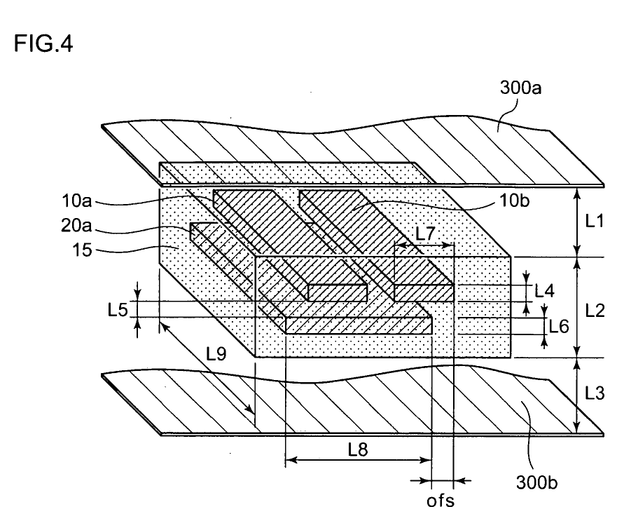

As described above, the first and second signal current wiring lines 10a and 10b and the return current wiring line 20a are arranged in the casing 300 in a stacked manner with a predetermined distance D2 (which corresponds to the distance L5 shown in FIG. 4) opened between them. By stacking the wiring lines as described above, the space required to mount the wiring lines between the circuit blocks can be reduced. Furthermore, by stacking the wiring lines, such an arrangement provides the first signal current wiring line 10a, the second signal current wiring line 10b, and the return current wiring line 20a with stable impedances.

### EMBODIMENT

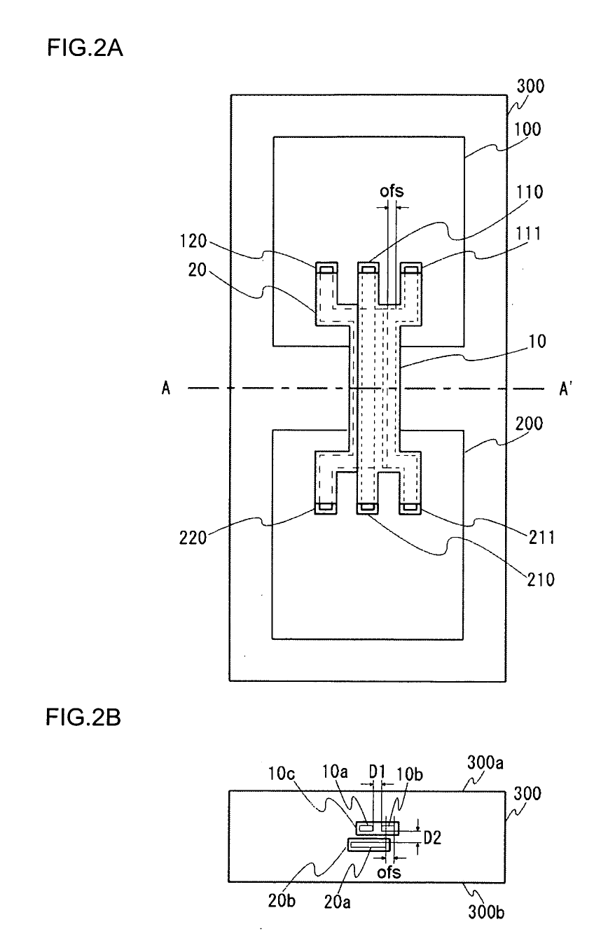

FIG. 2A and FIG. 2B are diagrams which show a casing 300 which stores a first circuit block 100 and a second circuit block 200 according to an embodiment. FIG. 2A is a diagram which shows the interior of the casing 300 viewed from the top. FIG. 2B is a cross-sectional view of the casing 300 taken along the line A-A′ shown in FIG. 2A.

In FIG. 2B, the first signal current wiring line 10a, the second signal current wiring line 10b, and the return current wiring line 20a are stacked with an offset between them in the width direction (horizontal direction in the drawing), whereby a region is formed where the second signal current wiring line 10b faces the second face (the bottom face in the description of the present specification) 300b of the casing 300 without the return current wiring line 20a intervening between the second face 300b of the casing 300 and the first and second signal current wiring lines 10a and 10b (note that the first signal current wiring line 10a faces the second face 300b of the casing 300 with the return current wiring line 20a intervening between them). This offset will be referred to as the “offset ofs” in this specification. FIG. 2B shows an arrangement in which the signal current wiring board 10 and the return current wiring board 20 are stacked with the return current wiring board 20 offset toward the left of the signal current writing board 10. In the drawing, the two signal current wiring lines, i.e., the first signal current wiring line 10a and the second signal current wiring line 10b, are arranged with a predetermined distance D1 opened between them in the width direction. Furthermore, the signal current wiring lines and the return current wiring line 20a are arranged with a predetermined distance D2 opened between them.

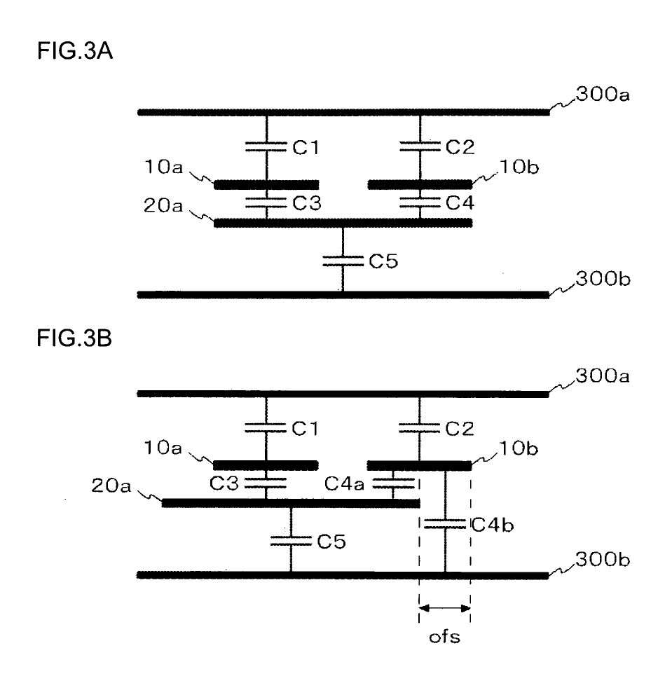

FIG. 3A and FIG. 3B are schematic diagrams for describing parasitic capacitance that occurs in the wiring structure shown in FIG. 1A, FIG. 1B, FIG. 2A and FIG. 2B. In general, the capacitance C is defined by the following Expression 1.

C=εS/d (Expression 1)

Here, ε represents the dielectric constant of an insulating material provided between electrodes, S represents the area of the electrodes, and d represents the distance between electrodes.

FIG. 3A shows parasitic capacitance that occurs in the wiring structure shown in FIG. 1A and FIG. 1B. A first parasitic capacitance C1 occurs between a first face 300a (top face in description in the present specification) of the casing 300 and the first signal current wiring line 10a. A second parasitic capacitance C2 occurs between the first face 300a of the casing 300 and the second signal current wiring line 10b. A third parasitic capacitance C3 occurs between the first signal current wiring line 10a and the return current wiring line 20a. A fourth parasitic capacitance C4 occurs between the second signal current wiring line 10b and the return current wiring line 20a. A fifth parasitic capacitance C5 occurs between the return current wiring line 20a and the second face 300b of the casing 300.

The electric potential of the first face 300a and the second face 300b of the casing 300 is essentially the same as the ground electric potential. Also, the electric potential of the return current wiring line 20a is essentially the same as the ground electric potential. Accordingly, the fifth parasitic capacitance has very little effect on the signal currents that flow through the other current wiring lines 10a and 10b. On the other hand, the first through fourth parasitic capacitances C1 through C4 each have a structure in which either the first signal current wiring line 10a or the second signal current wiring line 10b acts as one electrode of a capacitor. Accordingly, the first through fourth parasitic capacitances C1 through C4 have a great effect on the signal current that flows through the first signal current wiring line 10a or the signal current that flows through the second signal current wiring line 10b.

With reference to the aforementioned Expression 1, in order to reduce the first through fourth parasitic capacitances C1 through C4, there is a need to reduce the dielectric constant of the insulating material between the electrodes, to reduce the area of the electrodes, or to increase the distance between the electrodes. Description will be made below under the assumption that the following are specified values: the dielectric constant of the insulating material between the first face 300a of the casing 300 and the first signal current wiring line 10a and the second signal current wiring line 10b; the wiring line widths of the first signal current wiring line 10a, the second signal current wiring line 10b, and the return current wiring line 20a; and the distance between the first face 300a and the second face 300b of the casing 300.

FIG. 3B shows parasitic capacitance that occurs in the wiring structure shown in FIG. 2A and FIG. 2B. In the wiring structure shown in FIG. 3B, the second signal current wiring line 10b and the return current wiring line 20a are arranged with an offset ofs between them that is half the wiring line width of the second signal current wiring line 10b. Accordingly, the capacitance that occurs below the second signal current wiring line 10b is broken down into a first fourth parasitic capacitance C4a that occurs between the second signal current wiring line 10b and the return current wiring line 20a and a second fourth parasitic capacitance C4b that occurs between the second signal current wiring line 10b and the second face 300b of the casing 300. The combined capacitance of the first fourth parasitic capacitance C4a and the second fourth parasitic capacitance C4b is smaller than the fourth parasitic capacitance C4 shown in FIG. 3A. It should be noted that the first through third parasitic capacitances C1 through C3 and the fifth parasitic capacitance C5 are the same as those shown in FIG. 3A.

As described above, by providing such an offset ofs, the parasitic capacitance can be reduced without changing the distance between the first face 300a and the second face 300b of the casing 300, or changing the wiring line widths of the first signal current wiring line 10a, the second signal current wiring line 20b, and the return current wiring line 20a. Where the offset ofs is made even larger, the parasitic capacitance can be further reduced. However, this increases the wiring space in the width direction. That is to say, there is a tradeoff relation between the offset ofs and the wiring space in the width direction.

In a case in which there are multiple signal current wiring lines provided in the width direction as described in the present embodiment, the multiple signal current wiring lines 10a and 10b and the return current wiring line 20a are preferably arranged such that at least a part of the area, in the width direction, of the signal current wiring line 10b, which is selected from among the multiple signal current wiring lines 10a and 10b as the high-speed signal line via which the highest-speed signal is to be transmitted, faces the second face 300b of the casing 300 without the return current wiring line 20a intervening between them. Such an arrangement is capable of reducing the parasitic capacitance that occurs at the signal current wiring line that is most sensitive to signal loss because of the effect of the parasitic capacitance.

Here, the signal transmitted via the first signal current wiring line 10a is the CD signal, and the signal transmitted via the second signal current wiring line 10b is the DVD signal. In this case, the latter signal is transmitted at a higher speed. Accordingly, the aforementioned offset ofs is provided between the second signal current wiring line 10b and the return current wiring line 20a.

FIG. 4 is a diagram which shows the setting conditions used to simulate the relation between the offset and the signal loss in a wiring structure according to the embodiment. Here, copper wiring is employed as the first signal current wiring line 10a, the second signal current wiring line 10b, and the return current wiring line 20a. Furthermore, the first signal current wiring line 10a, the second signal current wiring line 10b, and the return current wiring line 20a are coated with a polyimide film, thereby forming a wiring board 15.

The distance L1 between the first face 300a of the casing 300 and the wiring board 15 is 2.0 mm. The thickness L2 of the wiring board 15 is 0.18 mm. The distance L3 between the wiring board 15 and the second face 300b of the casing 300 is 2.0 mm. The wiring line thickness L4 of the first signal current wiring line 10a and the second signal current wiring line 10b are each 0.02 mm. The distance L5 between the first and second signal current wiring lines 10a and 10b and the return current wiring line 20a is 0.1 mm. The wiring line thickness L6 of the return current wiring line 20a is 0.02 mm. The wiring line width L7 of the first signal current wiring line 10a and the second signal current wiring line 10b are each 1.0 mm. The wiring line width L8 of the return current wiring line 20a is 2.5 mm. The wiring line length L9 of the first signal current wiring line 10a, the second signal current wiring line 10b, and the return current wiring line 20a are each 20 mm.

Also, the second circuit block 200, which is not shown, functions as a 50Ω load.

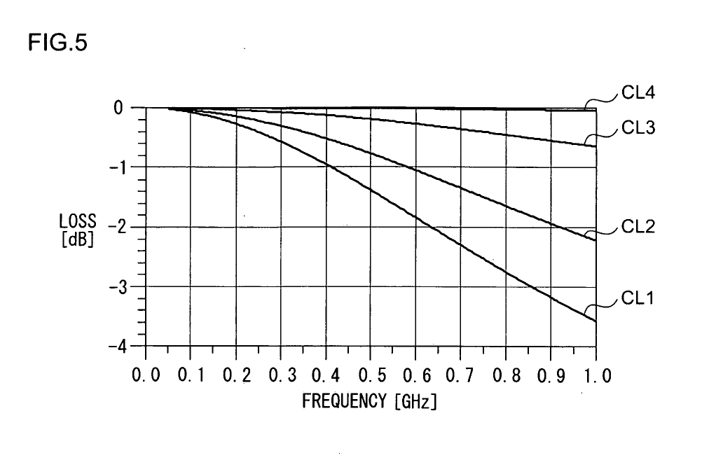

FIG. 5 is a graph showing the simulation result of the relation between the offset and the signal loss in the wiring structure according to the embodiment. In the graph shown in FIG. 5, the horizontal axis represents the frequency [GHz] of the signal transmitted through the second signal current wiring line 10b, and the vertical axis represents the signal loss [dB] that occurs in the second signal current wiring line 10b.

Here, simulations were performed of four wiring structures having different offsets between the second signal current wiring line 10b and the return current wiring line 20a. That is to say, simulations were performed of wiring structures where the offset ofs was zero, where the offset ofs was ⅓ the wiring line width L7 of the signal current wiring line 10b, where the offset ofs was half the wiring length L7, and where the offset ofs was the same width as the wiring length L7.

In FIG. 5, the first characteristics line CL1 represents the characteristics of a wiring structure where the offset ofs is zero. The second characteristics line CL2 represents the characteristics of a wiring structure where the offset ofs is ⅓ the width of the wiring line width L7. The third characteristics line CL3 represents the characteristics of a wiring structure where the offset ofs is half the width of the wiring line width L7. The fourth characteristics line CL4 represents the characteristics of a wiring structure where the offset ofs is the same width as the wiring length L7. Thus, it is made clear that, as the signal frequency becomes higher, the signal loss decreases according to the increase in the offset ofs.

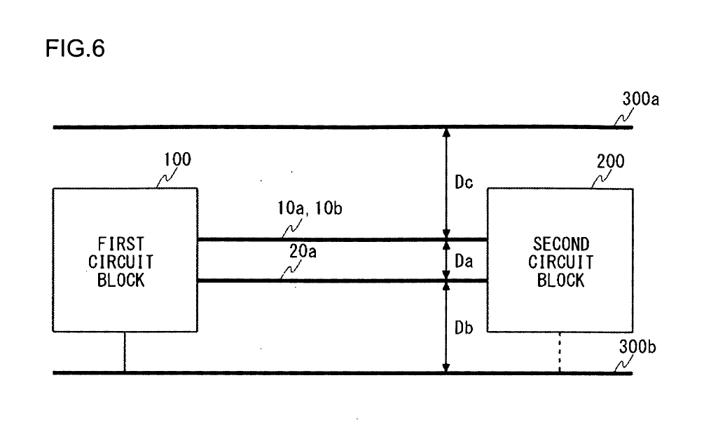

FIG. 6 is a schematic diagram for describing the distance relations between the first face 300a of the casing 300, the signal current wiring lines 10a and 10b, the return current wiring line 20a, and the second face 300b of the casing 300 according to the embodiment.

The signal current wiring lines 10a and 10b and the return current wiring line 20a may be arranged in the casing 300 such that the distance Dc between the first face 300a and the signal current wiring lines 10a and 10b is greater than the distance Db between the return current wiring line 20a and the second face 300b. As shown in FIG. 3A and FIG. 3B, such an arrangement increases the fifth parasitic capacitance C5, which has little effect on the signal loss, and reduces the first and second parasitic capacitances C1 and C2, which have a great effect on the signal loss.

Also, in order to provide the same effects, the dielectric constant of the insulating material between the first face 300a and the signal current wiring lines 10a and 10b may be designed to be a lower dielectric constant than that of the insulating material between the return current wiring line 20a and the second face 300b, instead of, or in addition to, the wiring structure in which the layout of the signal current wiring lines 10a and 10b and the return current wiring line 20a is adjusted as described above. Here, the dielectric constant may be a combined dielectric constant comprising the dielectric constant of the dielectric material and the dielectric constant of the air. Thus, the designer can configure an appropriate dielectric constant with a desired value by adjusting at least one of: the selection of the dielectric material, the thickness of the dielectric material, and the width of the space.

Also, the signal current wiring lines 10a and 10b and the return current wiring line 20a may be arranged in the casing 300 such that the distance Dc between the first face 300a and the signal current wiring lines 10a and 10b is greater than the distance Da between the signal current wiring lines 10a and 10b and the return current wiring line 20a. Such an arrangement reduces the area of the current loop region formed by the current that flows through the signal current wiring lines 10a and 10b and the return current wiring line 20a, thereby suppressing unnecessary electromagnetic wave radiation.

As described above, with the present embodiment having a wiring structure in which the signal current wiring lines 10a and 10b and the return current wiring line 20a are arranged in a stacked manner, the signal current wiring lines 10a and 10b and the return current wiring line 20a are stacked with an offset between them in the width direction. Such a structure reduces signal loss in the signal current wiring line 10b.

Also, the distance Dc between the first face 300a of the casing 300 and the signal current wiring lines 10a and 10b may be designed to be greater than the distance Db between the return current wiring line 20a and the second face 300b of the casing 300. Such an arrangement further reduces signal loss in the signal current wiring line 10b.

### APPLICATIONS

Description will be made regarding an application in which the wiring structure according to the above-described embodiment is applied to an optical disk apparatus.

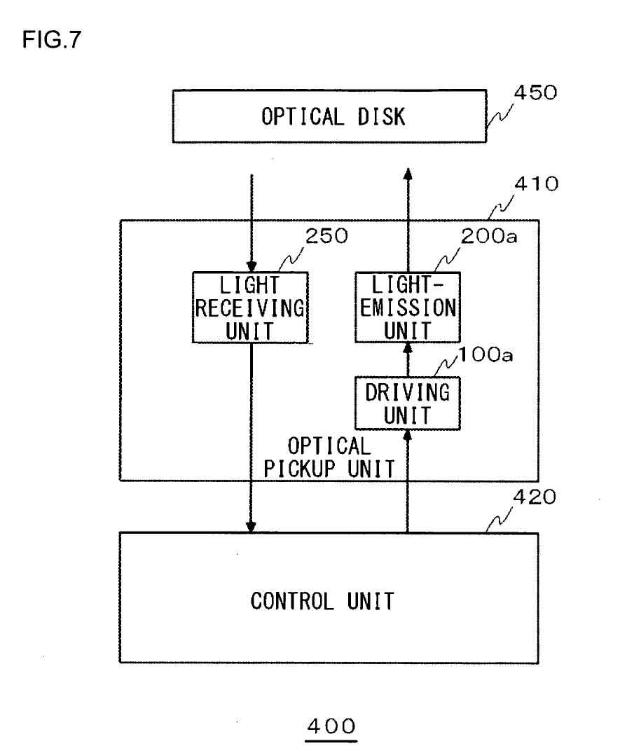

FIG. 7 is a block diagram which shows the configuration of an optical disk apparatus 400 according to an application. The optical disk apparatus 400 includes an optical pickup unit 410 and a control unit 420. The optical pickup unit 410 includes a driving unit 100a, a light-emission unit 200a, and a light receiving unit 250.

The optical pickup unit 410 reads out data from an optical disk 450 mounted on the optical disk apparatus 400. Alternatively, the optical pickup unit 410 writes data to the optical disk 450. The control unit 420 controls the overall operation of the optical disk apparatus 400. For example, the control unit 420 transmits a data readout signal or a data writing signal to the driving unit 100a.

The light-emission unit 200a emits laser light toward the optical disk 450. The driving unit 100a drives the light-emission unit 200a. The light receiving unit 250 receives reflected light from the optical disk 450. The wiring structure according to the above-described embodiment is employed in the wiring lines that connect the driving unit 100a and the light-emission unit 200a. That is to say, a signal current wiring line, via which a driving signal current is to be carried from the driving unit 100a to the light-emission unit 200a, and a return current wiring line, via which a return current is to be carried from the light-emission unit 200a to the driving unit 100a, are provided.

A laser diode included in the light-emission unit 200a is basically driven by DC current. Furthermore, in order to reduce return light noise, a high-frequency current (e.g., 340 MHz) is superimposed on the DC current. The high-frequency current is provided as a sine-wave signal or a rectangular-wave signal. The term “return light noise” refers to a portion of the reflected light from the optical disk 450 that returns to the laser diode and acts as interference noise which interferes with the light emitted from the laser diode. By employing the wiring structure according to the above-described embodiment, such an application suppresses signal loss that occurs in the high-frequency current which is transmitted from the driving unit 100a to the light-emission unit 200a.

The wiring structure according to the above-described embodiment is suitably applied to the optical pickup unit 410. In recent years, such optical pickups often have a configuration in which multiple laser diodes (e.g., for CDs, for DVDs, for BDs) are integrated, which leads to a situation in which such signal wiring lines easily become concentrated. Furthermore, as progress is made in providing increasingly low-profile devices, there is a trend toward a reduction in the wiring space. Also, accompanying the increased capacity of optical disks, the lasers are progressively higher powered, leading to a trend toward an increase in the wiring line width. Also, as optical disk access speeds become faster, there is a trend toward an increase in the quantity of signals.

As described above, in recent years, with respect to such pickups, there has been a trend toward reduction in the distance between the signal current wiring lines and the casing, and a trend toward an increase in the signal wiring line width. This leads to an increase in the parasitic capacitance. However, by employing the wiring structure according to the above-described embodiment, such an application reduces the parasitic capacitance without changing the distance between the signal current wiring lines and the casing, and without changing the signal wiring line width. Thus, such an application reduces signal loss.

The present invention is not restricted to the above-described embodiments. Also, various modifications may be made with respect to the layout and so forth based upon the knowledge of those skilled in this art. Such modifications of the embodiments are also encompassed by the scope of the present invention.

### MODIFICATION 1

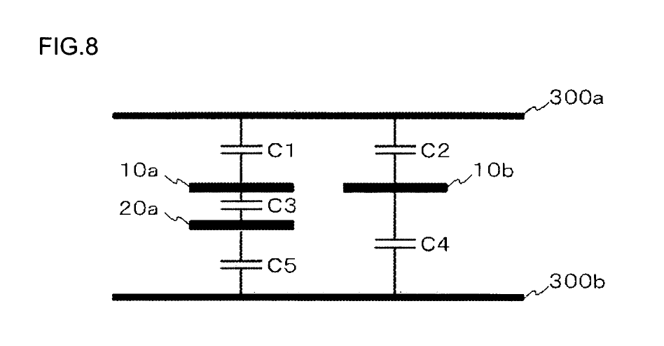

FIG. 8 is a schematic diagram for describing the parasitic capacitance that occurs in the wiring structure according to a modification 1. In the modification 1, the wiring line width of the return current wiring line 20a corresponds to the wiring line widths of the first signal current wiring line 10a and the second signal current wiring line 10b, and the return current wiring line 20a is arranged such that it coincides with the first signal current wiring line 10a in the width direction. Such a modification provides the characteristics represented by the fourth characteristics line CL4 shown in FIG. 5. It should be noted that the wiring line width of the return current wiring line 20a is required to satisfy the maximum current requirement described above.

### MODIFICATION 2

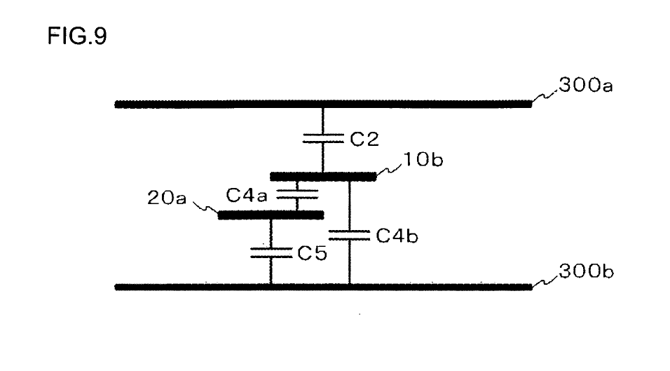

FIG. 9 is a schematic diagram for describing the parasitic capacitance that occurs in the wiring structure according to a modification 2. Description has been made in the above-described embodiment and modification 1 regarding an arrangement including multiple (two) signal current wiring lines. Also, the present invention can be applied to an arrangement including a single signal current wiring line 10b, which provides the same advantage. Also, an arrangement may be made in which the signal current wiring line 10b and the return current wiring line 20a form a differential line.

### MODIFICATION 3

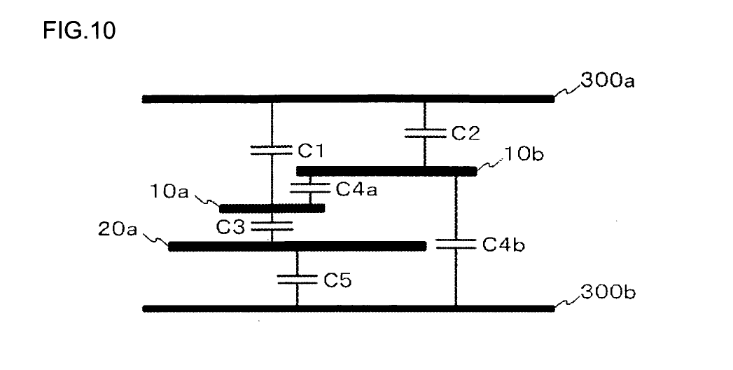

FIG. 10 is a schematic diagram for describing the parasitic capacitance that occurs in the wiring structure according to a modification 3. Description has been made in the above-described embodiment and modifications 1 and 2 regarding an arrangement in which the signal current wiring lines and the return current wiring line are stacked in a two-layer structure. Also, the present invention can be applied to an arrangement in which the wiring layers are stacked in a structure of three or more layers. FIG. 10 shows an arrangement in which the first signal current wiring line 10a and the second signal current wiring line 10b are arranged as separate layers. With such an arrangement, the return current wiring line 20a is arranged with an offset in the width direction (to the left in FIG. 10), thereby reducing the fourth parasitic capacitance C4.

### MODIFICATION 4

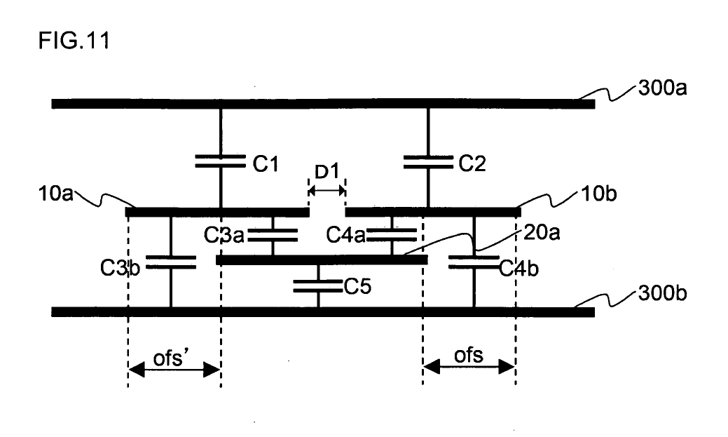

FIG. 11 is a schematic diagram for describing the parasitic capacitance that occurs in the wiring structure according to a modification 4. In the wiring structure shown in FIG. 11, the second signal current wiring line 10b and the return current wiring line 20a are arranged with an offset ofs between them, in the same way as shown in FIG. 3B. Furthermore, in the wiring structure shown in FIG. 11, the first signal current wiring line 10a and the return current wiring line 20a are arranged with an offset ofs′ between them. Such a structure can be realized by making the width of the return current wiring line 20a smaller than the sum of the widths of the first signal current wiring line 10a and the second signal current wiring line 10b, and the distance D1 between the first signal current wiring line 10a and the second signal current wiring line 10b.

Accordingly, in the same way as shown in FIG. 3B, the capacitance that occurs below the second signal current wiring line 10b can be broken down into a first fourth parasitic capacitance C4a that occurs between the second signal current wiring line 10b and the return current wiring line 20a and a second fourth parasitic capacitance C4b that occurs between the second signal current wiring line 10b and the second face 300b of the casing 300. Furthermore, the capacitance that occurs below the first signal current wiring line 10a can be broken down into a first third parasitic capacitance C3a that occurs between the first signal current wiring line 10a and the return current wiring line 20a and a second third parasitic capacitance C3b that occurs between the first signal current wiring line 10a and the second face 300b of the casing 300.

That is to say, in FIG. 3B, the second signal current wiring line 10b has a portion that directly faces the second face 300b, and the first signal current wiring line 10a has no portion that directly faces the second face 300b. Contrastingly, in FIG. 11, in the same way as the second signal current wiring line 10b, the first signal current wiring line 10a also has a portion that directly faces the second face 300b. As a result, the combined capacitance of the first third parasitic capacitance C3a and the second third parasitic capacitance C3b is smaller than the third parasitic capacitance C3 shown in FIG. 3B. As described above, by providing the offset ofs′ in addition to the offset ofs, such an arrangement further reduces the parasitic capacitance.

Description has been made regarding an arrangement in which a laser diode driver is employed as the first circuit block 100, and a laser diode is employed as the second circuit block 200. However, the first circuit block 100 and the second circuit block 200 are not restricted to such examples. For example, an arrangement may be made in which a DSP (Digital Signal Processor) is employed as the first circuit block 100 and a CMOS image sensor or a CCD sensor is employed as the second circuit block 200. The above-described wiring structure can be employed in a digital still camera or a digital video camera.

What is claimed is:

1. A wiring structure comprising:
a first wiring line configured to carry a signal current from a first circuit block to a second circuit block; and
a second wiring line provided as a separate layer from that of the first wiring line, and configured to carry a return current from the second circuit block to the first circuit block,
wherein the first wiring line and the second wiring line are arranged in a casing, with a predetermined distance between them,
and wherein a region is formed between a surface of the casing on the second wiring line side and the first wiring line where the first wiring line faces the surface of the casing on the second wiring line side without the second wiring line intervening between them.

2. A wiring structure according to claim 1, wherein the first wiring line and the second wiring line are arranged within the casing such that the distance between the surface of the casing on the first wiring line side and the first wiring line is greater than the distance between the second wiring line and the surface of the casing on the second wiring line side.

3. A wiring structure according to claim 1, wherein the dielectric constant of a material provided between the surface of the casing on the first wiring line side and the first wiring line is designed to be smaller than that of a material provided between the second wiring line and the surface of the casing on the second wiring line side.

4. A wiring structure according to claim 2, wherein the dielectric constant of a material provided between the surface of the casing on the first wiring line side and the first wiring line is designed to be smaller than that of a material provided between the second wiring line and the surface of the casing on the second wiring line side.

5. A wiring structure according to claim 1, wherein a plurality of first wiring lines are provided,
and wherein the plurality of first wiring lines and the second wiring line are arranged such that a region is formed where one first wiring line, via which a highest-rate signal is to be transmitted, selected from among the plurality of first wiring lines, faces the surface of the casing on the second wiring line side without the second wiring line intervening between them.

6. A wiring structure according to claim 2, wherein a plurality of first wiring lines are provided,
and wherein the plurality of first wiring lines and the second wiring line are arranged such that a region is formed where one first wiring line, via which a highest-rate signal is to be transmitted, selected from among the plurality of first wiring lines, faces the surface of the casing on the second wiring line side without the second wiring line intervening between them.

7. A wiring structure according to claim 3, wherein a plurality of first wiring lines are provided,
and wherein the plurality of first wiring lines and the second wiring line are arranged such that a region is formed where one first wiring line, via which a highest-rate signal is to be transmitted, selected from among the plurality of first wiring lines, faces the surface of the casing on the second wiring line side without the second wiring line intervening between them.

8. A wiring structure according to claim 4, wherein a plurality of first wiring lines are provided,
and wherein the plurality of first wiring lines and the second wiring line are arranged such that a region is formed where one first wiring line, via which a highest-rate signal is to be transmitted, selected from among the plurality of first wiring lines, faces the surface of the casing on the second wiring line side without the second wiring line intervening between them.

9. An optical disk apparatus comprising:
a light-emission unit configured to emit laser light toward an optical disk;
a driving unit configured to drive the light-emission unit;
a first wiring line configured to carry a driving signal current from the driving unit to the light-emission unit;
a second wiring line provided as a separate layer from that of the first wiring line, and configured to carry a return current from the light-emission unit to the driving unit,
wherein the first wiring line and the second wiring line are arranged in a casing, with a predetermined distance between them,
and wherein a region is formed between a surface of the casing on the second wiring line side and the first wiring line where the first wiring line faces the surface of the casing on the second wiring line side without the second wiring line intervening between them.
